(19) United States
(12) Patent Application Publication
(10) Pub. No.: US 2026/0173933 A1
(43) Pub. Date: Jun. 18, 2026

(54) INTERPOSER WITH ENHANCED ELECTRICAL ISOLATION AND METHODS FOR FORMING THE SAME

(71) Applicant: Taiwan Semiconductor Manufacturing Company Limited, Hsinchu (TW)

(72) Inventors: Chen-Shien Chen, Hsinchu (TW); Hsu-Hsien Chen, Hsinchu City (TW); Yinlung Lu, Hsinchu (TW); Yao-Chun Chuang, Hsinchu City (TW); Jyun-Lin Wu, Hsinchu City (TW)

(21) Appl. No.: 18/981,601

(22) Filed: Dec. 15, 2024

(51) Int. Cl. H01L 23/498; H01L 21/265; H01L 21/324; H01L 21/48; H01L 23/00; H01L 23/64; H01L 25/16; H05K 1/18; H10B 80/00

(52) U.S. Cl. CPC H10W 70/685; H10P 30/204; H10P 30/21; H10P 95/90; H10W 70/093; H10W 70/095; H10W 70/65; H05K 1/181; H10B 80/00; H10W 44/601; H10W 72/0198; H10W 72/252; H10W 72/29; H10W 72/90; H10W 72/923; H10W 72/952; H10W 74/15; H10W 90/00; H10W 90/401; H10W 90/724; H10W 90/734

(57) ABSTRACT

A semiconductor structure may be provided by: forming a semiconductor device in an upper portion of a substrate; forming through-substrate via structures in the upper portion of the substrate; thinning the substrate by removing material portions of the substrate from a backside, whereby backside end surfaces of the through-substrate via structures are exposed; forming at least one backside isolation layer by implanting ions of at least one non-electrical dopant element into a backside portion of the substrate; and forming backside bump structures on the backside end surfaces of the through-substrate via structures.

### BACKGROUND

Embedded semiconductor devices such as embedded capacitors in an interposer may have undesirable leakage current paths. Such leakage current paths degrade the performance of the embedded devices and increase power consumption of the embedded devices. Improved electrical isolation structures and techniques are desired.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of a unit area of a substrate after formation of semiconductor devices (such as deep trench capacitors) according to an embodiment of the present disclosure.

FIG. 1B is a top-down view of the substrate of FIG. 1A. The vertical plane A-A′ is the cut plane for the vertical cross-sectional view of FIG. 1A.

FIG. 2 is a vertical cross-sectional view of the unit area of the substrate after formation of via cavities, dielectric liners, and through-substrate via structures according to an embodiment of the present disclosure.

FIG. 3 is vertical cross-sectional view of the unit area of the substrate after formation of redistribution dielectric layers and redistribution wiring interconnects according to an embodiment of the present disclosure.

FIG. 4 is a vertical cross-sectional view of the unit area of the substrate after attaching semiconductor dies according to an embodiment of the present disclosure.

FIG. 5 is a vertical cross-sectional view of an embodiment structure after formation of underfill material portions and a molding compound matrix according to an embodiment of the present disclosure.

FIG. 6 is a vertical cross-sectional view of a reconstituted wafer obtained by thinning the substrate according to an embodiment of the present disclosure.

FIG. 7 is a vertical cross-sectional view of the reconstituted wafer after covering through-substrate via structures with patterned photoresist material portions according to an embodiment of the present disclosure.

FIG. 8 is a vertical cross-sectional view of the reconstituted wafer after performing two ion implantation processes that form a first backside implantation layer and a second backside implantation layer according to an embodiment of the present disclosure.

FIG. 9A is a vertical cross-sectional view of the reconstituted wafer after performing an anneal process that converts the first backside implantation layer and the second backside implantation layer into a first backside isolation layer and a second backside isolation layer according to an embodiment of the present disclosure.

FIG. 9B illustrates vertical compositional profiles for non-electrical dopants that are present within a backside portion of a substrate of an interposer according to an embodiment of the present disclosure.

FIG. 10 is a vertical cross-sectional view of the reconstituted wafer after formation of a backside passivation layer according to an embodiment of the present disclosure.

FIG. 11 is a vertical cross-sectional view of the reconstituted wafer after formation of backside bump structures and backside solder material portions according to an embodiment of the present disclosure.

FIG. 12 is vertical cross-sectional view of a composite package formed by dicing the reconstituted wafer according to an embodiment of the present disclosure.

FIG. 13 is a vertical cross-sectional view of a bonded assembly of a composite package and a packaging substrate according to an embodiment of the present disclosure.

FIG. 14 is a vertical cross-sectional view of a bonded assembly of a composite package, a packaging substrate, and a printed circuit board according to an embodiment of the present disclosure.

FIG. 15 is a vertical cross-sectional view of a first alternative configuration of a bonded assembly of a composite package, a packaging substrate, and a printed circuit board according to an embodiment of the present disclosure.

FIG. 16 is a vertical cross-sectional view of a second alternative configuration of a bonded assembly of a composite package, a packaging substrate, and a printed circuit board according to an embodiment of the present disclosure.

FIG. 17 is a vertical cross-sectional view of a third alternative configuration of a bonded assembly of a composite package, a packaging substrate, and a printed circuit board according to an embodiment of the present disclosure.

FIG. 18 is a vertical cross-sectional view of a fourth alternative configuration of a bonded assembly of a composite package, a packaging substrate, and a printed circuit board according to an embodiment of the present disclosure.

FIG. 19 is a first flowchart illustrating steps for forming a semiconductor structure according to an embodiment of the present disclosure.

FIG. 20 is a second flowchart illustrating steps for forming a semiconductor structure according to an embodiment of the present disclosure.

### DETAILED DESCRIPTION

The following disclosure provides many different embodiments, or examples, for implementing various features of the provided subject matter. Specific examples of components and arrangements are described below to simplify the present disclosure. These are merely examples, and are not limiting. Drawings are not drawn to scale. Elements with the same reference numerals refer to the same element, and are presumed to have the same material composition and the same thickness range unless expressly indicated otherwise. All features of an original embodiment are presumed to be present in any derived embodiment unless expressly disclosed otherwise. Thus, features described with reference to related embodiments in the drawings and/or in the specification provide support for features in an embodiment. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Further, spatially relative terms, such as “beneath,” “below,” “lower,” “above,” “upper” and the like, may be used herein for ease of description to describe geometrical features among elements as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Various embodiments disclosed herein may be directed to semiconductor structures, and particularly to a package structure including an interposer with at least one backside isolation layer formed by ion implantation of non-electrical dopants. Various embodiments disclosed herein provide an interposer including semiconductor devices such as deep trench capacitors and providing reduced leakage current. Semiconductor devices formed within an interposer may have undesirable leakage paths to through-substrate via structures. Various embodiments disclosed herein provide at least one backside isolation layer by implanting ions of at least one non-electrical dopant element, such as oxygen or nitrogen, into a backside portion of an interposer substrate. The at least one backside isolation layer, located between the semiconductor bump structures and the backside bump structures, reduces leakage current by enhancing electrical isolation. Various aspects of embodiments of the present disclosure are now described with reference to accompanying figures.

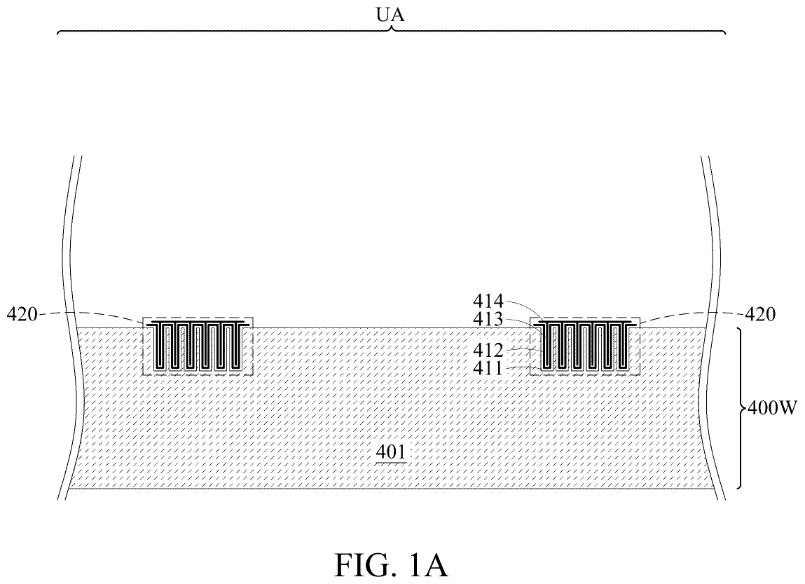

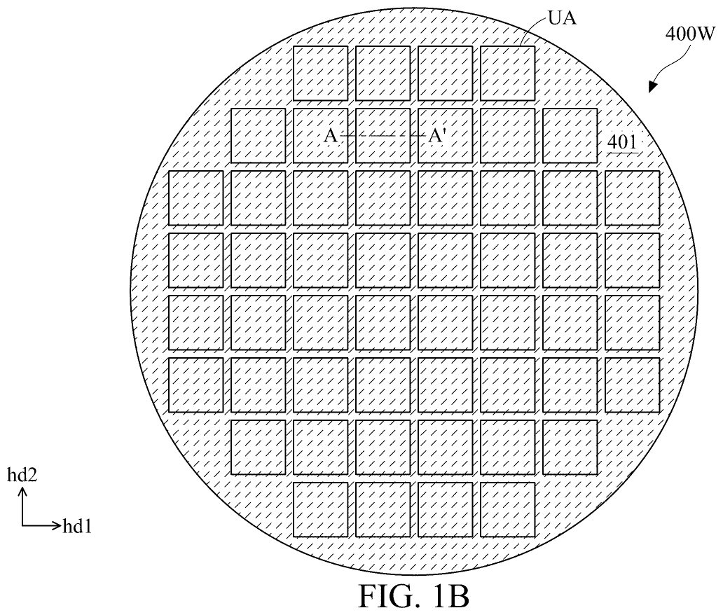

Referring to FIGS. 1A and 1B, a substrate 400W is illustrated, which may be used to form a reconstituted wafer that may be subsequently diced into interposers. In one embodiment, the substrate 400W may comprise a semiconductor wafer such as a commercially available single crystalline silicon wafer or a polycrystalline wafer. The lateral dimensions (such as a diameter) of the substrate 400W may be in a range from 150 mm to 450 mm, although lesser or greater diameters may be used. The thickness of the substrate 400W may be in a range from 500 microns to 2,000 microns, although lesser or greater thicknesses may also be used.

The substrate 400W may be large enough to contain a two-dimensional array of unit areas UA. Each unit area UA corresponds to the area of an interposer to be subsequently formed. The substrate 400W comprises a substrate semiconductor layer 401. Semiconductor devices may be formed in a top portion of the substrate semiconductor layer 401 within each unit area UA. The unit areas UA may be arranged as a two-dimensional periodic array such as a rectangular periodic array having a first periodicity along a first horizontal direction hd1 and having a second periodicity along a second horizontal direction hd2.

The semiconductor devices may comprise active semiconductor devices such as field effect transistors, and/or may comprise passive semiconductor devices such as capacitors, inductors, resistors, etc. In an illustrative example, the semiconductor devices that are formed in, or on, an upper portion of the substrate semiconductor layer 401 may comprise deep trench capacitors 420 as known in the art. While the present disclosure is described using an embodiment in which deep trench capacitors 420 are formed in an upper portion of the substrate semiconductor layer 401, embodiments are expressly contemplated herein in which any other type of semiconductor devices (such as field effect transistors, bipolar transistors, optical semiconductor devices, or other types of passive semiconductor devices) are formed in, or on, the upper portion of the substrate semiconductor layer 401 in addition to, or in lieu of, the deep trench capacitors 420.

As used herein, a deep trench refers to a trench having a greater depth than 0.5 micron. The depth of the deep trenches for the deep trench capacitors 420 may be in a range from 1 micron to 10 microns, although lesser or greater depths may also be used. Each deep trench capacitor 420 may comprise a layer stack (411, 412, 413, 414) that is formed within a respective set of at least one deep trench. The layer stack may include an optional isolation dielectric layer 411 that provides electrical isolation from the substrate semiconductor layer 401, at least one first electrode layer 412, at least one node dielectric layer 413, and at least one second electrode layer 414. The at least one first electrode layer 412 may comprise a single electrode layer or a plurality of electrode layers that are spaced apart by at least one combination of a respective second electrode layer 414 and a respective pair of node dielectric layers 413. The at least one second electrode layer 414 may comprise a single electrode layer or a plurality of electrode layers that are spaced apart by at least one combination of a respective first electrode layer 412 and a respective pair of node dielectric layers 413.

While the deep trench capacitors 420 are illustrated using a configuration in which each deep trench capacitor 420 comprises one node dielectric layer 413, one first electrode layer 412, and one second electrode layer 414, embodiments are expressly contemplated herein in which three or more electrode layers (412, 414) are used for a deep trench capacitor 420. Generally, if the total number of the at least one node dielectric layer is N (N≥1), the total number of the electrode layers (412, 414) may be N+1. The total number of the first electrode layers 412 may be the greatest integer that does not exceed (N+2)/2, and the total number of the second electrode layers 414 may be the greatest integer that does not exceed (N+1)/2. The number N may be in a range from 1 to 10, although a greater number may also be used.

Each of the electrode layers (412, 414) may comprise a metallic material that is resistant to reaction with neighboring dielectric materials. For example, each of the electrode layers (412, 414) may comprise a material such as TiN, TaN, WN, MON, W, Ti, Ta, etc. Each of the electrode layers (412, 414) may be deposited by a conformal deposition process such as a chemical vapor deposition process. Each of the electrode layers (412, 414) may have a thickness in a range from 5 nm to 100 nm, such as from 10 nm to 50 nm, although lesser or greater thicknesses may also be used.

Each of the node dielectric layers 413 comprises at least one node dielectric material, which may comprise a dielectric metal oxide material providing a dielectric constant greater than 7.9 (i.e., a high-k dielectric material), silicon nitride (having a dielectric constant of 7.9), and/or a high band gap dielectric material having a band gap greater than 6.0 eV and providing effective protection against charge carrier tunneling. In some embodiments, the node dielectric layers 413 may comprise aluminum oxide or a dielectric metal oxide of a transition metal. Additionally or alternatively, the node dielectric layers 413 may comprise an ONO stack. The node dielectric layers 413 may be deposited by chemical vapor deposition and/or atomic layer deposition. The thickness of each node dielectric layer 413 may be in a range from 4 nm to 50 nm depending on the operational voltage for the deep trench capacitors 420. Shallow trench isolation structures (not illustrated) may be formed as needed prior to, or after, formation of the deep trench capacitors 420.

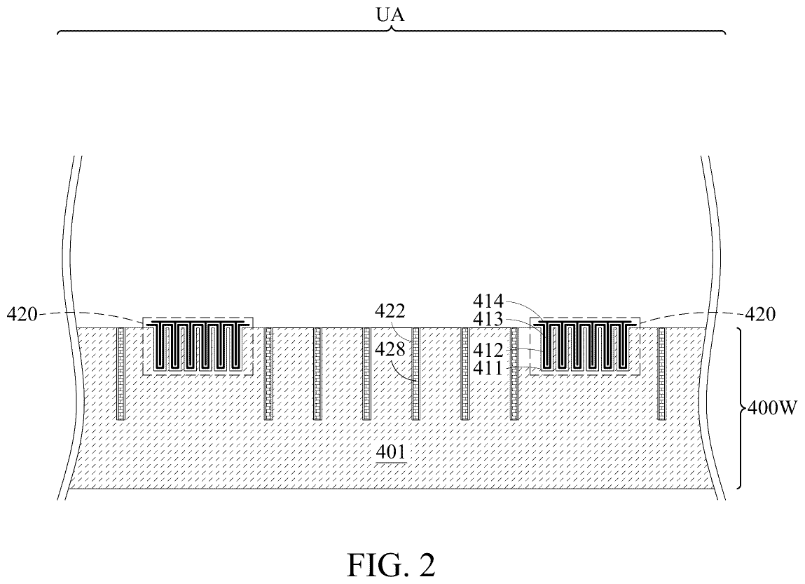

Referring to FIG. 2, via cavities may be formed in an upper portion of the substrate semiconductor layer 401. According to an aspect of the present disclosure, the via cavities have a depth that is greater than the depth of the deep trenches that are used for the deep trench capacitors 420. For example, the depth of the via cavities may be greater than the depth of the deep trenches of the deep trench capacitors 420 by a depth differential. The depth differential may be in a range from 1 micron to 10 microns, although lesser or greater depth differentials may also be used. In one embodiment, the depth of the via cavities may be in a range from 2 microns to 20 microns, such as from 5 microns to 10 microns.

A dielectric liner material such as silicon oxide may be conformally deposited in the via cavities. The thickness of the dielectric liner material may be in a range from 10 nm to 200 nm, although lesser or greater thicknesses may also be used. At least one metallic fill material may be deposited in remaining unfilled volumes of the via cavities. The at least one metallic fill material may comprise a metallic material that is resistant to diffusion into the dielectric liner material. For example, the at least one metallic fill material may comprise TiN, TaN, WN, MON, Ti, Ta, W, etc.

Excess portions of the dielectric liner material and the at least one metallic fill material may be removed from outside the via cavities. For example, a first isotropic etch process may be performed to etch portions of the at least one metallic material from above the top surface of the substrate semiconductor layer 401, and a second isotropic etch process may be performed to etch portions of the dielectric liner material from above the top surface of the substrate semiconductor layer 401. In some embodiments, etch stop layers (not illustrated) may be formed above the deep trench capacitors prior to deposition of the dielectric liner material and the at least one metallic fill material to protect the deep trench capacitors 420 during removal of horizontally-extending portions of the dielectric liner material and the at least one metallic fill material.

Each remaining portion of the dielectric liner material that remains in a peripheral region of a respective via cavity constitutes a dielectric liner 422. Each remaining portion of the at least one metallic material that remains in a center region of a respective via cavity constitutes a conductive via structure, which is herein referred to as a through-substrate via structure 428. While the through-substrate via structures 428 do not vertically extend through the substrate 400W at this processing step, the through-substrate via structures 428 may vertically extend through the substrate 400W upon subsequent thinning of the substrate 400W from the backside. Thus, each via cavity may be filled with a respective combination of a dielectric liner 422 and a through-substrate via structure 428. An array of through-substrate via structures 428 may be formed in the upper portion of the substrate 400W within each unit area UA.

While the present disclosure is described using an embodiment in which semiconductor devices (such as the deep trench capacitors 420) are formed prior to formation of through-substrate via structures 428, the through-substrate via structures 428 may be formed prior to formation of a subset of, or the entirety of, the semiconductor devices. Embodiments are thus expressly contemplated herein in which the order of formation of the through-substrate via structures 428 and any subset of the semiconductor devices is reversed.

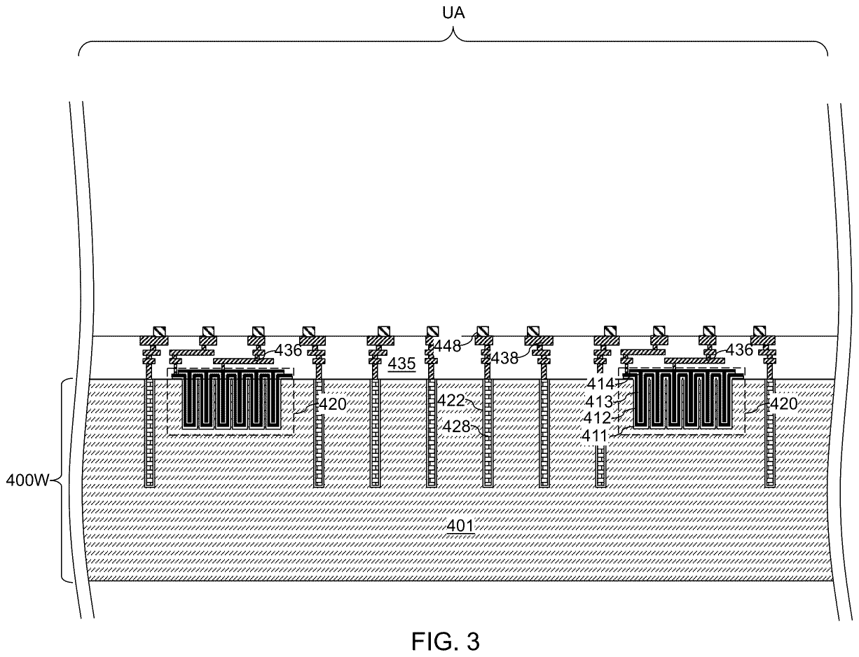

Referring to FIG. 3, a redistribution structure (435, 436, 438) may be formed on the front side of the substrate 400W within each unit area UA. The redistribution structure (435, 436, 438) comprises redistribution wiring interconnects (436, 438) that are embedded within redistribution dielectric layers 435. Each of the redistribution dielectric layers 435 may comprise a respective dielectric polymer material such as polyimide (PI), benzocyclobutene (BCB), or polybenzobisoxazole (PBO). The thickness of each redistribution dielectric layer 435 may be in a range from 2 microns to 40 microns, such as from 4 microns to 20 microns. The redistribution wiring interconnects (436, 438) may comprise metal via portions 436 that provide vertically-extending electrically conductive paths and metal line portions 438 that provide horizontally-extending electrically conductive paths. Each of the redistribution wiring interconnects (436, 438) may comprise a metallic seed layer and a metal layer (which may comprise, for example, copper, nickel, or copper and nickel). The thickness of each horizontally-extending portion of the redistribution wiring interconnects (436, 438) may be in a range from 2 microns to 40 microns, such as from 4 microns to 10 microns, although lesser or greater thicknesses may also be used. The redistribution wiring interconnects (436, 438) provide various electrically conductive paths through the redistribution dielectric layers 435. The total number of wiring levels, i.e., the total number of the levels of the metal line portions 438, of the redistribution wiring interconnects (436, 438) may be in a range from 1 to 12, although a greater number may also be used.

Interposer bump structures 448 may be formed on the redistribution wiring interconnects (436, 438). For example, an under bump material (UBM) layer may be deposited over the topmost surface of the redistribution dielectric layer 435. The UBM layer may comprise a layer stack including at least one adhesion layer and a metallic seed layer that functions as a template for initiating a subsequent electroplating process. For example, the UBM layer may comprise a layer stack that includes, from bottom to top, a titanium layer, a titanium nitride layer, a copper seed layer, and a nickel layer. The nickel layer may provide the functionality of serving as a barrier to prevent copper diffusion into the solder material, thereby enhancing the long-term reliability of the bump structure.

A photoresist layer (not shown) may be deposited over the UBM layer and may be lithographically patterned to form openings over the areas of a subset of the redistribution wiring interconnects (436, 438) located at the topmost level of the redistribution dielectric layers 435. In one embodiment, openings through the photoresist layer may be formed over each of the topmost metal via portions 436. An electroplating process may be subsequently performed to deposit an electroplatable material (such as copper) within the openings in the photoresist layer. Copper pillar structures may be electroplated within the openings in the photoresist layer. The lateral dimensions of each copper pillar structure may be in a range from 5 micron to 50 microns. The height of each copper pillar structure may be in a range from 10 microns to 40 microns. In one embodiment, the copper pillar structures may be formed as microbump structures. The photoresist layer may be subsequently removed, for example, by ashing. Unmasked portions of the UBM layer (which are not covered by the copper pillar structures) may be subsequently removed by performing an etch process, which may comprise an isotropic etch process such as a wet etch process. Remaining contiguous combinations of a respective patterned portion of the UBM layer and a respective copper pillar structure comprise interposer bump structures 448.

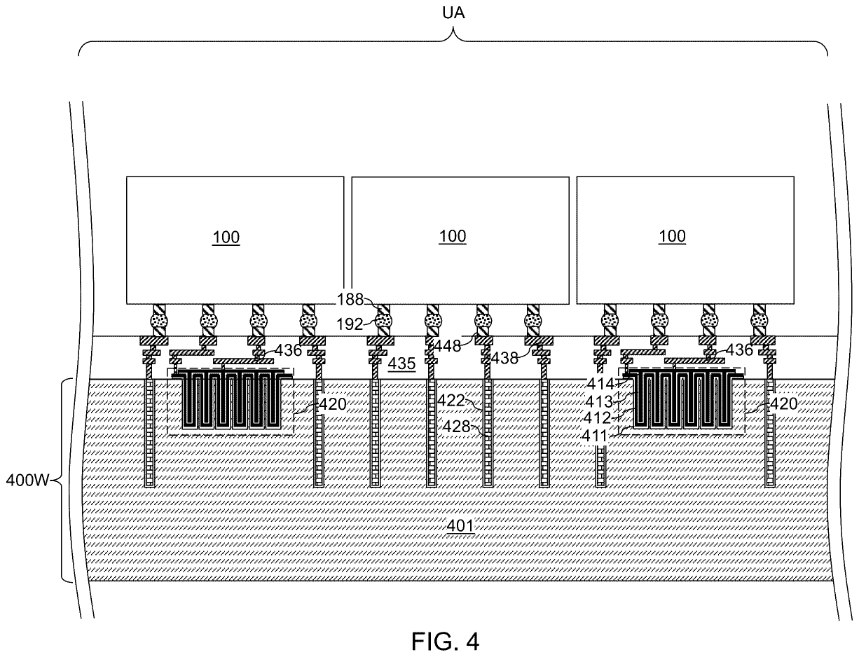

Referring to FIG. 4, a set of at least one semiconductor die 100 may be bonded to a respective set of interposer bump structures 448 within each unit area UA. Each set of at least one semiconductor die 100 includes at least one semiconductor die 100, and may comprise a plurality of semiconductor dies 100. In one embodiment, each set of at least one semiconductor die 100 may include at least one processor die and/or at least one memory die. Each processor die may comprise at least one central processor unit (CPU), at least one graphic processor unit (GPU), at least one neural processor unit (NPU), and/or at least one digital signal processor (DSP). In one embodiment, the at least one processor die may comprise a system-on-chip (SoC) die such as an application processor die. In one embodiment, the at least one memory die may comprise a high bandwidth memory (HBM) die that includes a vertical stack of static random access memory dies. Each HBM die may comprise a vertical stack of static random access memory (SRAM) dies that are interconnected to one another through arrays of microbumps and are laterally surrounded by a respective molding material enclosure frame.

Each semiconductor die 100 may comprise a respective array of on-die bump structures 188. Each of the semiconductor dies 100 may be positioned in a face-down position such that on-die bump structures 188 face the solder material portions 192. Placement of the semiconductor dies 100 may be performed using a pick and place apparatus such that each of the on-die bump structures 188 may face a respective one of the solder material portions 192. Each set of at least one semiconductor die 100 may be placed within a respective unit area.

In one embodiment, the on-die bump structures 188 and the interposer bump structures 448 may be configured for microbump bonding. In this embodiment, each of the on-die bump structures 188 and the interposer bump structures 448 may be configured as copper pillar structures having a diameter in a range from 10 microns to 50 microns, and may have a respective height in a range from 10 microns to 40 microns. The pitch of the microbumps in the direction of periodicity may be in a range from 20 microns to 100 microns, although lesser or greater pitches may also be used. Upon reflow, the solder material portions 192 provide solder-mediated bonding between vertically-neighboring pairs of an on-die bump structures 188 and an interposer bump structure 448.

Generally, at least one semiconductor die 100 comprising a respective array of on-die bump structures 188 may be attached to a respective subset of the interposer bump structures 448 in each unit area UA. In one embodiment, the at least one semiconductor die 100 is attached to interposer bump structures 448 using at least one array of solder material portions 192. In one embodiment, each of the at least one semiconductor die 100 comprises a respective array of on-die bump structures 188 that is bonded to a respective subset of the interposer bump structures 448.

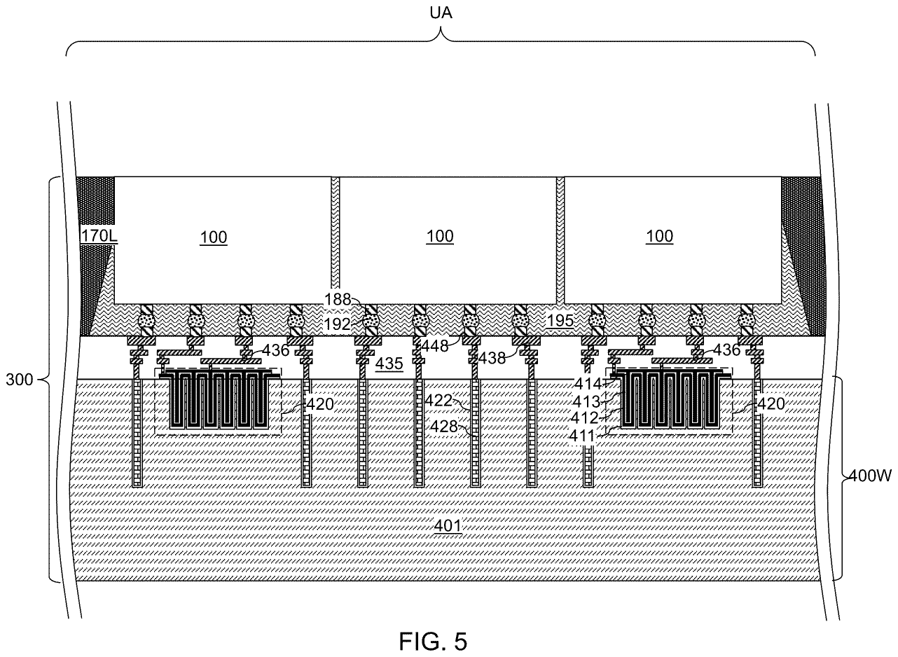

Referring to FIG. 5, an underfill material may be applied into each gap between the redistribution structures (435, 436, 438) and a respective set of at least one semiconductor die 100. The underfill material may comprise any underfill material known in the art. The underfill material may be applied into the gap between the redistribution structures (435, 436, 438) and the at least one semiconductor die 100 around the solder material portions 192 within each unit area UA. An underfill material portion 195 may be formed by injecting the underfill material around the solder material portions 192 in a respective unit area UA. Any known underfill material application method may be used, which may be, for example, the capillary underfill method, the molded underfill method, or the printed underfill method.

Thus, an underfill material portion 195 may be formed within each unit area UA between a redistribution structure (435, 436, 438) and the respective set of at least one semiconductor die 100. Generally, at least one semiconductor die 100 comprising a respective set of on-die bump structures 188 is attached to a redistribution structure (435, 436, 438) through a respective set of solder material portions 192 within each unit area UA. The underfill material portion 195 may laterally surround, and contact, all solder material portions 192, the interposer bump structures 448, and the on-die bump structures 188 in the unit area UA.

A molding compound (MC) may be applied to the gaps between assemblies of a respective set of semiconductor dies 100 and a respective underfill material portion 195. The MC may include epoxy resin, hardener, silica (as a filler material), and other additives. The MC may be cured at a curing temperature to form a molding compound matrix, which is herein referred to as a die-level molding compound matrix or as a molding compound matrix 170L. The molding compound matrix 170L laterally surrounds and embeds each assembly of a set of semiconductor dies 100 and an underfill material portion 195. The molding compound matrix 170L includes a plurality of molding compound (MC) die frames that are laterally adjoined to one another. Each MC die frame is a portion of the molding compound matrix 170L that is located within a respective unit area UA. Thus, each MC die frame laterally surrounds, and embeds, a respective a set of semiconductor dies 100 and a respective underfill material portion 195. Young's modulus of pure epoxy is about 8.35 GPa, and Young's modulus of the MC may be higher than Young's modulus of pure epoxy due to additives therein. Thus, Young's modulus of the molding compound matrix 170L may be greater than 8.5 GPa.

Portions of the molding compound matrix 170L that overlies the horizontal plane including the top surfaces of the semiconductor dies 100 may be removed by a planarization process. For example, the portions of the molding compound matrix 170L that overlies the horizontal plane may be removed using a chemical mechanical planarization (CMP). The combination of the substrate 400W and device structures therein, a two-dimensional array of redistribution structures (435, 436, 438), the semiconductor dies 100, the underfill material portions 195, and the molding compound matrix 170L constitutes a reconstituted wafer 300 Each portion of the molding compound matrix 170L located within a unit area UA constitutes an MC die frame.

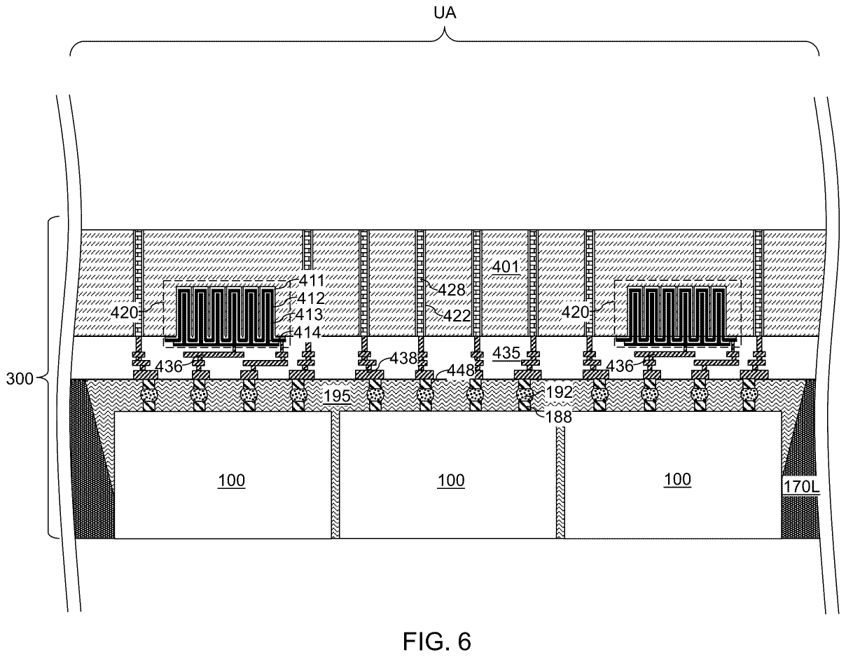

Referring to FIG. 6, the substrate 400W of the reconstituted wafer 300 may be thinned by removing material portions of the substrate 400W from the backside. The backside portion of the substrate semiconductor layer 401 may be removed, for example, by grinding, polishing, an anisotropic etch process, and/or an isotropic etch process. The removal of the backside portion of the substrate semiconductor layer 401 may proceed until backside end surfaces of the through-substrate via structures 428 are exposed. In one embodiment, a terminal processing step of the thinning process may comprise a polishing process that uses the through-substrate via structures 428 as endpoint detection structures. In one embodiment, the physically exposed backside horizontal surface of the substrate semiconductor layer 401 may be coplanar with the physically exposed backside surfaces of the through-substrate via structures 428 and the dielectric liners 4282.

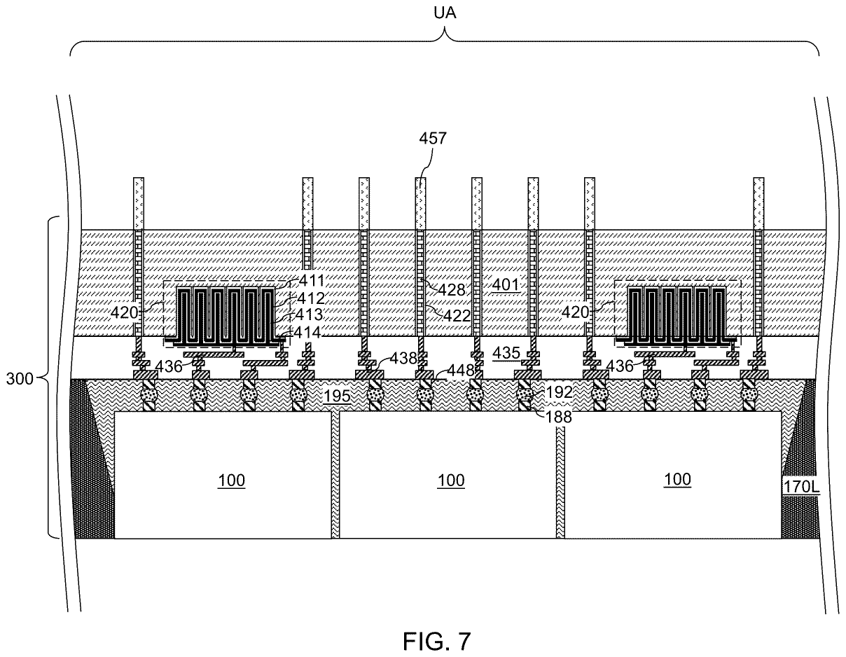

Referring to FIG. 7, a photoresist material layer may be applied to the physically exposed backside horizontal surface of the substrate semiconductor layer 401, and can be lithographically patterned into photoresist material portions 457 covering each of the through-substrate via structures 428. In one embodiment, the thickness of the dielectric liners 422 may be selected such that the overlay variation of the lithographic patterning process that patterns the photoresist material potions 457 is less than the thickness of the dielectric liners 422. In other words, by selecting the thickness of the dielectric liners 422 to be greater than the overlay variation of the lithographic patterning process that patterns the photoresist material potions 457, all sidewalls of the photoresist material portions 457 may be formed between an inner sidewall of an underlying dielectric liner 422 and an outer sidewall of the underlying dielectric liner 422 in a plan view (such as a top-down view). In an illustrative example, the thickness of the dielectric liner 422 may be in a range from 200 nm to 2 microns, such as from 500 nm to 1 micron, although lesser or greater thicknesses may also be used. The thickness (i.e., the vertical extent) of the photoresist material portions 457 may be selected to be greater than the maximum implantation depth of the implantation processes to be subsequently employed for the photoresist material. For example, the thickness of the photoresist material portions 457 may be in a range from 0.5 micron to 3 microns, such as from 1 micron to 2 microns, although lesser or greater thicknesses may also be used.

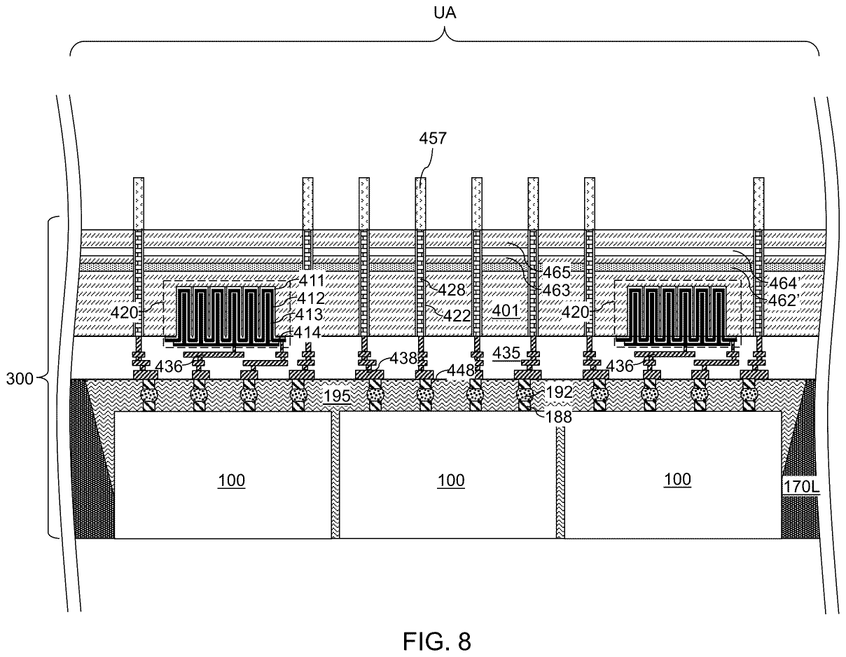

Referring to FIG. 8, at least one ion implantation process may be performed to implant at least one non-electrical dopant element. As used herein, a non-electrical dopant element refers to a dopant element that does not provide charge carriers in a semiconductor material. For example, the at least one non-electrical dopant element may comprise nitrogen and/or oxygen. The at least one non-electrical dopant element is implanted into portions of the reconstituted wafer 300 that are not masked by the photoresist material portions 457. Specifically, the photoresist material portions 457 prevent implantation of the at least one non-electrical dopant element into the through-substrate via structures 428, while allowing implantation of the at least one non-electrical dopant element into the substrate semiconductor layer 401. Generally, outer portions of the dielectric liners 422 that are proximal to the substrate semiconductor layer 401 may be implanted with the at least one non-electrical dopant, while inner portions of the dielectric liners 422 that are proximal to the through-substrate via structures 428 are protected from the ion beams used during the at least one ion implantation process by the photoresist material portions 457. Generally, the tilt angle of the ion beam(s) during each of the at least one ion implantation process may be 0 degree with respect to the vertical direction.

According to an aspect of the present disclosure, the species of the non-electrical dopant element in each ion implantation process, the energy of each ion implantation process, and the dose of each ion implantation process may be selected such that at least one backside implantation layer (462′, 464′) may be formed. Each of the at least one backside implantation layer (462′, 464′) includes a respective non-electrical dopant element at a sufficiently high atomic concentration such that each backside implantation layer (462′, 464′) is a dielectric material layer, i.e., a material layer that includes an electrically insulating material. In other words, each backside implantation layer (462′, 464′) is an electrical isolation layer, or a “backside isolation layer” that provides electrical isolation at the backside of the reconstituted wafer 300. Generally, ions of at least one non-electrical dopant element are implanted between the planar backside surface of the reconstituted wafer 300 (i.e., the physically exposed surface of the substrate semiconductor layer 401 as provided after the processing steps of FIG. 7) and the deep trench capacitors 420.

In one embodiment, the at least one backside implantation layer (462′, 464′) may comprise a first backside implantation layer 462′ that is formed at a greater depth from the physically exposed backside surface of the substrate semiconductor layer 401 as provided after the processing steps of FIG. 7, and a second backside implantation layer 464′ that is formed at a lesser depth from the physically exposed backside surface of the substrate semiconductor layer 401 as provided after the processing steps of FIG. 7. In this embodiment, two separate ion implantation processes may be performed to form the first backside implantation layer 462′ and the second backside implantation layer 464′.

In one embodiment, the first backside implantation layer 462′ and the second backside isolation layer 464′ may be vertically spaced from each other by a first backside semiconductor layer 463 that comprises an unimplanted portion of the substrate semiconductor layer 401. Further, the second backside isolation layer 464′ may be vertically spaced from the physically exposed backside surface of the substrate semiconductor layer 401 as provided after the processing steps of FIG. 7. In this embodiment, another unimplanted portion of the substrate semiconductor layer 401, which is herein referred to as a second backside semiconductor layer 465, may be formed between the second backside isolation layer 464′ and the physically exposed backside surface of the substrate semiconductor layer 401 as provided after the processing steps of FIG. 7.

Generally, each of the at least one backside implantation layer (462′, 464′) comprises a dielectric compound of a respective non-electrical dopant element, which may be nitrogen or oxygen. In one embodiment, the at least one backside implantation layer (462′, 464′) comprises a first backside implantation layer 462′ and a second backside implantation layer 464′ that are formed at different depths from a planar backside surface of the substrate semiconductor layer 401 as formed through the processing steps of FIG. 7. A stack of two backside dielectric layers may be formed to increase the effectiveness of electrical isolation. In one embodiment, the semiconductor material of the substrate semiconductor layer 401 comprises silicon, the first backside implantation layer 462′ comprises silicon atoms and nitrogen atoms that are implanted as a non-electrical dopant element, and the second backside implantation layer 464′ comprises silicon atoms and oxygen atoms that are implanted as a non-electrical dopant element.

The depths of the implanted atoms of a non-electrical dopant element that is incorporated into the first backside implantation layer 462′ has a stochastic distribution, and is centered around a first peak depth, i.e., a depth at which the an implanted atom has the highest probability of stopping. The average depth of the implanted atoms of the non-electrical dopant element that is incorporated into the first backside implantation layer 462′ may be in a range from 60 nm to 400 nm, such as from 150 nm to 300 nm. The total dose of the implanted atoms of the non-electrical dopant element may be selected such that the first backside implantation layer 462′ is electrically insulating. For example, if the non-electrical dopant element that is incorporated into the first backside implantation layer 462′ is nitrogen, the dose of implanted nitrogen atoms may be in a range from 2×10¹⁷/cm³ to 1×10¹⁸/cm³, although lesser or greater doses may also be used.

Similarly, the depths of the implanted atoms of a non-electrical dopant element that is incorporated into the second backside implantation layer 464′ has a stochastic distribution, and is centered around a second peak depth, i.e., a depth at which the implanted atom has the highest probability of stopping. The average depth of the implanted atoms of the non-electrical dopant element that is incorporated into the second backside implantation layer 464′ may be in a range from 30 nm to 200 nm, such as from 75 nm to 150 nm. The total dose of the implanted atoms of the non-electrical dopant element may be selected such that the second backside implantation layer 464′ is electrically insulating. For example, if the non-electrical dopant element that is incorporated into the second backside implantation layer 464′ is oxygen, the dose of implanted oxygen atoms may be in a range from 1×10¹⁷/cm³ to 5×10¹⁷/cm³, although lesser or greater doses may also be used. The photoresist material portions 457 can be subsequently removed, for example, by ashing.

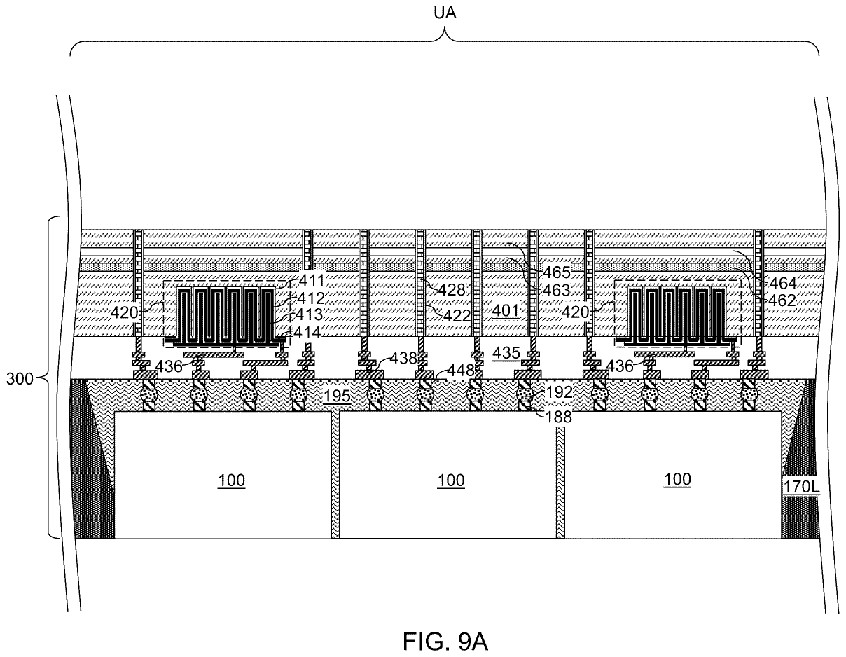

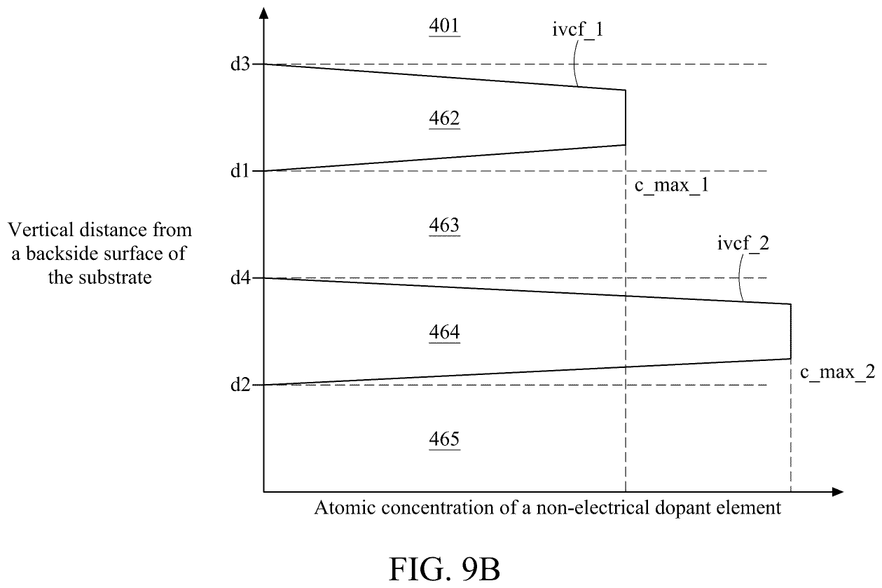

FIG. 9A is a vertical cross-sectional view of the reconstituted wafer 300 after performing an anneal process that converts the first backside implantation layer 462′ and the second backside implantation layer 464′ into a first backside isolation layer 462 and a second backside isolation layer 464 according to an embodiment of the present disclosure. FIG. 9B illustrates vertical compositional profiles for non-electrical dopants that are present within a backside portion of a substrate of an interposer according to an embodiment of the present disclosure.

Referring to FIGS. 9A and 9B, a laser anneal process may be performed to increase interatomic bonding between semiconductor atoms (such as silicon atoms) and implanted non-electrical dopant atoms within each of the first backside implantation layer 462′ and the second backside implantation layer 464′. The laser beam may be irradiated onto the first backside implantation layer 462′ and the second backside implantation layer 464′ from the backside of the substrate semiconductor layer 401, i.e., without passing through the redistribution structure (435, 436, 438), and thus, without substantially raising the temperature of the redistribution structure (435, 436, 438).

The use of a laser anneal process is advantageous because the laser anneal process may raise the temperature of the first backside implantation layer 462′ and the second backside implantation layer 464′ without excessively raising the temperature of various semiconductor devices (such as the deep trench capacitors 420) that are embedded within an upper region of the substrate semiconductor layer 401 and limiting the temperature within the redistribution dielectric layers 435 below 400 degrees Celsius (above which the various dielectric materials of the redistribution dielectric layers 435 may decompose). The local temperature of the first backside implantation layer 462′ and the second backside implantation layer 464′ may reach a peak in a range from 600 degrees Celsius to 900 degrees Celsius during the laser anneal process, which may be sufficiently high to effectively increase the interatomic bonding between the semiconductor atoms and atoms of the non-electrical dopant elements within the first backside implantation layer 462′ and the second backside implantation layer 464′.

For example, the nitrogen atoms implanted into the first backside implantation layer 462′ may bond with silicon atoms in the first backside implantation layer 462′ to form an inhomogeneous silicon nitride material having a vertical compositional modulation. Likewise, the oxygen atoms implanted into the second backside implantation layer 464′ may bond with silicon atoms in the second backside implantation layer 464′ to form an inhomogeneous silicon oxide material having a vertical compositional modulation.

In one embodiment, in regions (such as a middle region of the first backside implantation layer 462′) where the nitrogen atoms are sufficiently implanted to form a stoichiometric silicon nitride material, a stoichiometric silicon nitride material (Si₃N₄) may be formed. In regions (such as an upper region and a lower region of the first backside implantation layer 462′) where the atomic density of the nitrogen atoms is insufficient to form a stoichiometric silicon nitride material, a non-stoichiometric silicon nitride material (such as a silicon-rich silicon nitride material having a material composition of Si₃N_{4-δ} (0δ<4)) may be formed.

In one embodiment, in regions (such as a middle region of the second backside implantation layer 464′) where the oxygen atoms are sufficiently implanted to form a stoichiometric silicon oxide material, a stoichiometric silicon oxide material (SiO₂) may be formed. In regions (such as an upper region and a lower region of the second backside implantation layer 464′) where the atomic density of the oxygen atoms is insufficient to form a stoichiometric silicon oxide material, a non-stoichiometric silicon oxide material (such as a silicon-rich silicon oxide material having a material composition of SiO_{2-ϵ} (0<ϵ<2)) may be formed.

The first backside implantation layer 462′may be converted into a first backside isolation layer 462 through the laser anneal process. The first backside isolation layer 462 may have the same material composition as the first backside implantation layer 462′, but has an increased level of interatomic bonding between semiconductor atoms (such as silicon atoms) and atoms of a first non-electrical dopant element (which may be nitrogen or oxygen). Likewise, the second backside implantation layer 464′ is converted into a second backside isolation layer 464 through the laser anneal process. The second backside isolation layer 464 may have the same material composition as the second backside implantation layer 462′, but has an increased level of interatomic bonding between semiconductor atoms (such as silicon atoms) and atoms of a second non-electrical dopant element (which may be oxygen or nitrogen).

As illustrated in FIG. 9B, a substrate of the reconstituted wafer 300 may comprise a layer stack that includes, from front to backside, a substrate semiconductor layer 401 in direct contact with semiconductor devices (such as deep trench capacitors 420) and comprising a remaining portion of the substrate semiconductor layer 401 as provided after the processing steps of FIG. 7; a first backside isolation layer 462 located at a first depth d1 from the physically exposed backside surface of the substrate of the reconstituted wafer 300; a first backside semiconductor layer 463 that includes a first unimplanted portion of the substrate semiconductor layer 401 as provided after the processing steps of FIG. 7 and located at a fourth depth d4 from the physically exposed backside surface of the substrate of the reconstituted wafer 300; a second backside isolation layer 464 located at a second depth d2 from the physically exposed backside surface of the substrate of the reconstituted wafer 300; and a second backside semiconductor layer 465 that includes a second unimplanted portion of the substrate semiconductor layer 401 as provided after the processing steps of FIG. 7 containing the physically exposed backside surface of the substrate of the reconstituted wafer 300 as a backside surface. The depth of the substrate semiconductor layer 401 as measured from the physically exposed backside surface of the substrate of the reconstituted wafer 300 is herein referred to as a third depth d3.

Generally, the third depth d3 may be in a range from 100 nm to 600 nm. The first depth d1 may be in a range from 40% to 90% of the third depth d3. The fourth depth d4 may be in a range from 40% to 90% of the first depth d1. The second depth d2 may be in a range from 40% to 90% of the fourth depth. In one embodiment, the second depth may be in a range from 30 nm to 200 nm, such as from 50 nm to 150 nm, although lesser or greater depths may also be used.

Each of the at least one backside isolation layer (462, 464) comprises a respective dielectric compound of the at least one non-electrical dopant element and the semiconductor material. As discussed above, the anneal process increases a total number of interatomic bonds between atoms of the at least one non-electrical dopant element and atoms of the semiconductor material in each of the at least one backside isolation layer (462, 464).

In one embodiment, the first backside isolation layer 462 has a first inhomogeneous vertical compositional profile ivcf_1 so that the atomic concentration of the first non-electrical dopant element is at a maximum in a middle portion of the first backside isolation layer 462 and decreases along a first vertical direction from the middle portion toward an interface with the substrate semiconductor layer 401, and decreases along a second vertical direction (which is antiparallel to the first vertical direction) from the middle portion toward an interface with the first backside semiconductor layer 463. In one embodiment, the maximum of the atomic concentration of the first non-electrical dopant element may be a first maximum concentration c_max_1 that forms a first stoichiometric dielectric semiconductor compound (such as stoichiometric silicon nitride or stoichiometric silicon oxide) between the semiconductor element of the substrate semiconductor layer 401 and the first non-electrical dopant element.

In one embodiment, the second backside isolation layer 464 has a second inhomogeneous vertical compositional profile ivcf_2 so that the atomic concentration of the second non-electrical dopant element is at a maximum in a middle portion of the second backside isolation layer 464 and decreases along the first vertical direction from the middle portion toward an interface with the first backside semiconductor layer 463, and decreases along the second vertical direction (which is antiparallel to the first vertical direction) from the middle portion toward an interface with the second backside semiconductor layer 465. In one embodiment, the maximum of the atomic concentration of the second non-electrical dopant element may be a second maximum concentration c_max_2 that forms a second stoichiometric dielectric semiconductor compound (such as stoichiometric silicon nitride or stoichiometric silicon oxide) between the semiconductor element of the substrate semiconductor layer 401 and the second non-electrical dopant element.

In one embodiment, the first backside isolation layer 462 may comprise a layer stack including, from one side to another, a first non-stoichiometric dielectric material layer, a stoichiometric dielectric material layer, and a second non-stoichiometric dielectric layer. In one embodiment, the first backside isolation layer 462 may comprise a layer stack including, from one side to another, a first non-stoichiometric silicon nitride layer, a stoichiometric silicon nitride layer, and a second non-stoichiometric silicon nitride layer.

In one embodiment, the second backside isolation layer 464 may comprise a layer stack including, from one side to another, a first non-stoichiometric dielectric material layer, a stoichiometric dielectric material layer, and a second non-stoichiometric dielectric layer. In one embodiment, the second backside isolation layer 464 may comprise a layer stack including, from one side to another, a first non-stoichiometric silicon oxide layer, a stoichiometric silicon oxide layer, and a second non-stoichiometric silicon oxide layer.

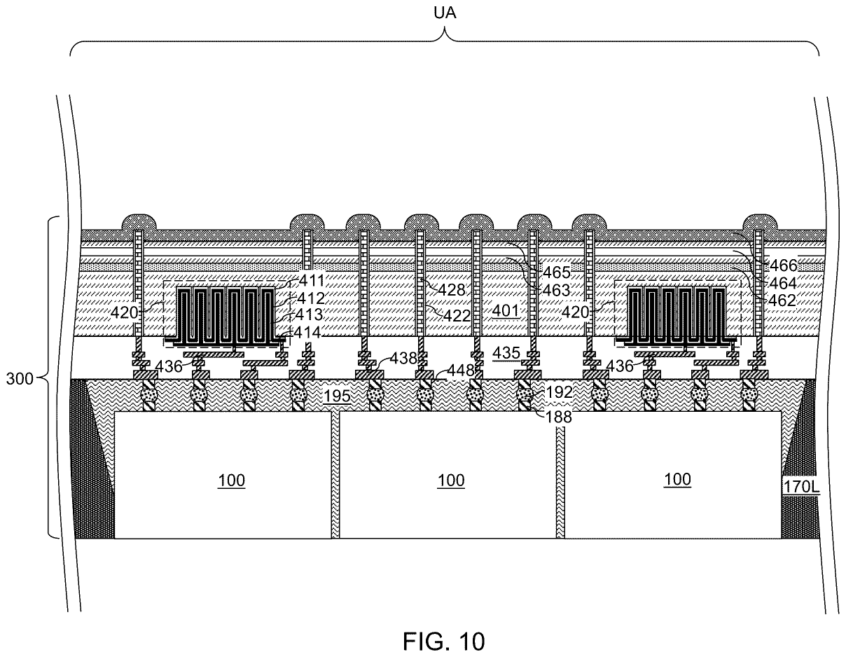

Referring to FIG. 10, a selective isotropic etch process may be optionally performed to vertically recess the physically exposed backside surface of the second backside semiconductor layer 465. For example, a wet etch process using potassium hydroxide (KOH) may be used to remove a backside surface portion of the second backside semiconductor layer 465 selectively to the materials of the through-substrate via structures 428 and the dielectric liners 422. The vertical recess distance may be in a range from 10 nm to 150 nm, such as from 30 nm to 100 nm, although lesser or greater vertical recess distances may also be used.

In embodiments in which the selective isotropic etch process is performed, a backside passivation layer 466 may be deposited on the physically exposed backside surface of the second backside semiconductor layer 465. The backside passivation layer 466 comprises at least one dielectric material such as silicon nitride, silicon oxide, silicon carbide nitride, and/or at least one dielectric metal oxide. In one embodiment, the backside passivation layer 466 may consist essentially of silicon nitride or silicon oxide. The thickness of the backside passivation layer 466 may be in a range from 10 nm to 200 nm, such as from 30 nm to 150 nm, although lesser or greater thicknesses may also be used.

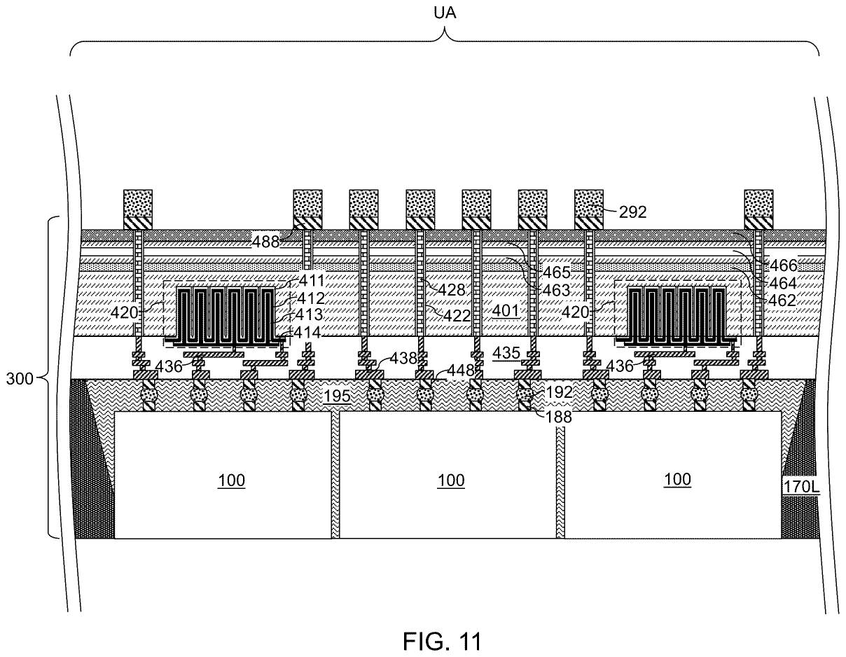

Referring to FIG. 11, a planarization process such as a chemical mechanical polishing process may be performed to remove protruding portions of the backside passivation layer 466. The planarization process may be terminated upon detection of the backside end surfaces of the through-substrate via structures 428. The substrate of the reconstituted wafer 300 comprises a layer stack including, from one side to another, a substrate semiconductor layer 401, a first backside isolation layer 462, a first backside semiconductor layer 463, a second backside isolation layer 464, a second backside semiconductor layer 465, and a backside passivation layer 466.

Backside bump structures 488 may be formed on the physically exposed end surfaces of the through-substrate via structures 428. For example, an under bump material (UBM) layer may be deposited over the end surfaces of the through-substrate via structures 428 and over the backside passivation layer 466. The UBM layer may comprise a layer stack including at least one adhesion layer and a metallic seed layer that functions as a template for initiating a subsequent electroplating process. For example, the UBM layer may comprise a layer stack that includes, from bottom to top, a titanium layer, a titanium nitride layer, a copper seed layer, and a nickel layer. The nickel layer may provide the functionality of serving as a barrier to prevent copper diffusion into the solder material, thereby enhancing the long-term reliability of the bump structure.

A photoresist layer (not shown) may be deposited over the UBM layer and may be lithographically patterned to form openings over the areas of a subset of the through-substrate via structures 428. An electroplating process may be subsequently performed to deposit an electroplatable material (such as copper) within the openings in the photoresist layer. Copper pad structures may be electroplated within the openings in the photoresist layer. The lateral dimensions of each copper pad structure may be in a range from 5 microns to 100 microns. The height of each copper pillar structure may be in a range from 10 microns to 60 microns. In one embodiment, the copper pad structures may be formed as microbump structures or as C4 bump structures. The photoresist layer may be subsequently removed, for example, by ashing. Unmasked portions of the UBM layer (which are not covered by the copper pillar structures) may be subsequently removed by performing an etch process, which may comprise an isotropic etch process such as a wet etch process. Remaining contiguous combinations of a respective patterned portion of the UBM layer and a respective copper pillar structure comprise backside bump structures 488.

Subsequently, solder material portions 292 may be formed on the backside bump structures 488. Specifically, the solder material portions 292 are attached to the backside bump structures 488. In one embodiment, the solder material portions 292 may be deposited by screen printing solder paste onto the backside bump structures 488. Alternatively, the solder material portions 292 may be disposed on the backside bump structures 488 by placing pre-formed solder balls on top of the backside bump structures 488. The solder material portions 292 may comprise a lead-free alloy such as a tin-silver-copper alloy. A reflow process may be performed to reflow the solder material portions 292, thereby attaching the solder material portions 292 to the backside bump structures 488.

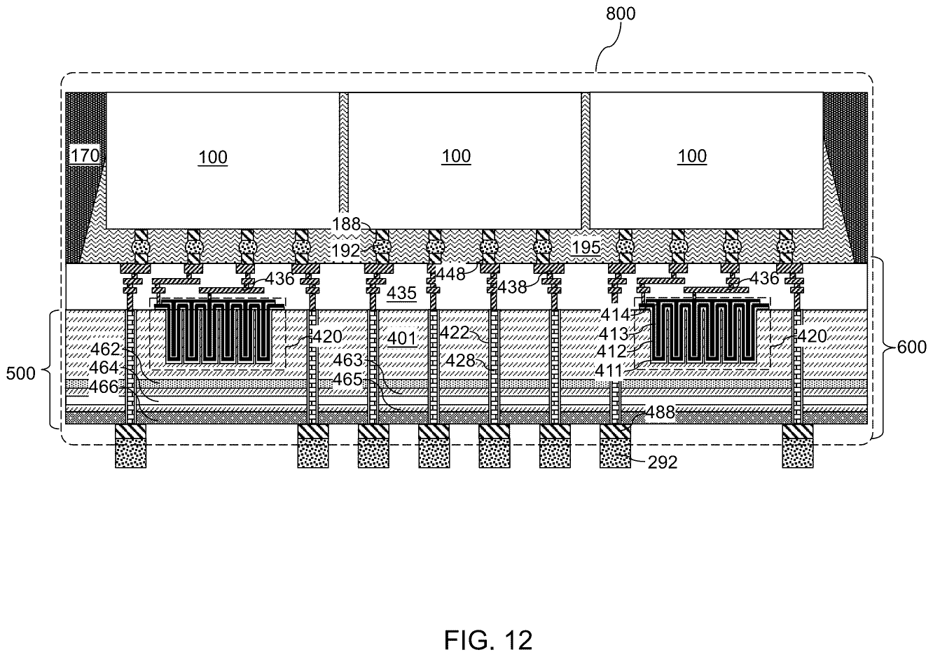

Referring to FIG. 12, the reconstituted wafer 300 may be diced along dicing channels to provide composite packages 800. The dicing channels correspond to the boundaries between neighboring pairs of unit areas UA. Each diced unit from the reconstituted wafer 300 comprises a composite package 800, which may be a fan-out package providing a fan-out connection configuration. Each diced portion of the molding compound matrix 170L constitutes an encapsulation frame 170, which is an encapsulation frame that encapsulates a set of at least one semiconductor die 100.

The diced portions of the reconstituted wafer comprise composite packages 800. Each composite package 800 comprises an interposer 600, at least one semiconductor die 100, at least one array of solder material portions 192, an underfill material portion 195, and an encapsulation frame 170. The interposer 600 comprises a substrate 500, semiconductor devices located in, or on, the substrate, a redistribution structure (435, 436, 438), interposer bump structures 448, and backside bump structures 488. The substrate 500 comprises a layer stack including, from one side to another, a substrate semiconductor layer 401, a first backside isolation layer 462, a first backside semiconductor layer 463, a second backside isolation layer 464, a second backside semiconductor layer 465, and a backside passivation layer 466.

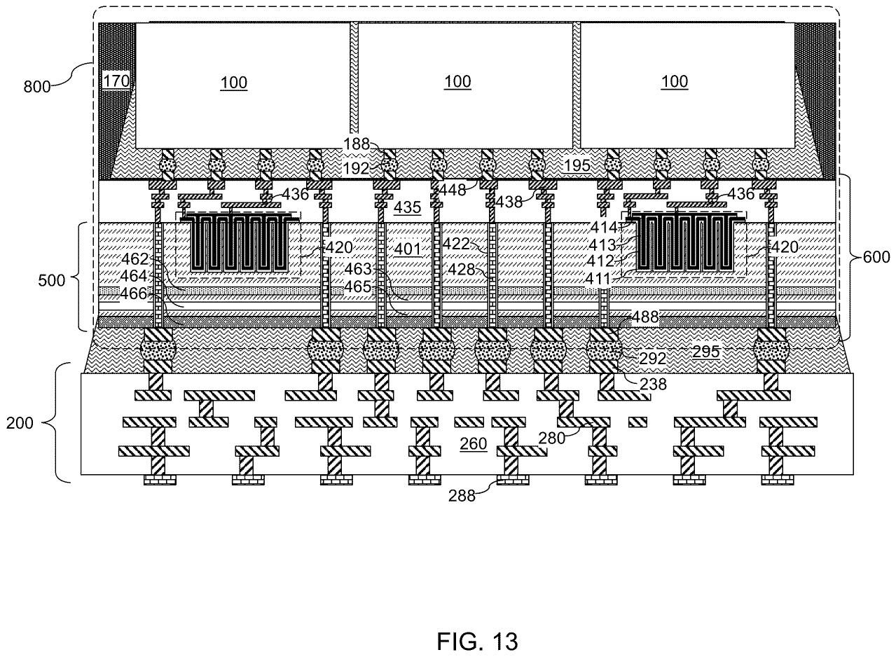

Referring to FIG. 13, a packaging substrate 200 may be provided. The packaging substrate 200 may be a cored packaging substrate including a core substrate, or a coreless packaging substrate that does not include a package core. Alternatively, the packaging substrate 200 may include a system-on-integrated packaging substrate (SoIS) including redistribution layers, dielectric interlayers, and/or at least one embedded interposer (such as a silicon interposer). Such a system-integrated packaging substrate may include layer-to-layer interconnections using solder material portions, microbumps, underfill material portions (such as molded underfill material portions), and/or an adhesion film. It is understood that the scope of the present disclosure is not limited by any particular type of substrate package. For example, an SoIS may be used in lieu of a cored packaging substrate. In embodiments in which SoIS is used, the core substrate may include a glass epoxy plate including an array of through-plate holes.

In one embodiment, the packaging substrate 200 may comprise substrate redistribution dielectric layers 260 having substrate redistribution wiring interconnects 280 formed therein. In one embodiment, the packaging substrate 200 may include board-side surface laminar circuit (SLC) and a chip-side surface laminar circuit (SLC). An array of package-side bonding pads 238 may be provided on the side of the packaging substrate 200 that faces the composite package 800. An array of board-side bonding pads 288 may be formed on the side of the packaging substrate 200 that is subsequently connected to a printed circuit board. The array of board-side bonding pads 288 may be configured to allow bonding through solder joints having a greater dimension than the C4 solder balls.

The composite package 800 may be attached to the packaging substrate 200 using an array of solder material portions 292. Specifically, each of the solder material portions 292 may be bonded to a respective one of the substrate-side bonding structures 488 and to a respective one of package-side bonding pads 238. A reflow process may be performed to reflow the solder material portions 292 during the bonding process.

An underfill material may be applied into a gap between the composite package 800 and the packaging substrate 200. The underfill material may comprise any underfill material known in the art. An underfill material portion may be formed around the array of solder material portions 292 in the gap between the composite package 800 and the packaging substrate 200. This underfill material portion is formed between the composite package 800 and the packaging substrate 200, and thus, is herein referred to as an interposer-package underfill material portion 295, or as an IP underfill material portion 295.

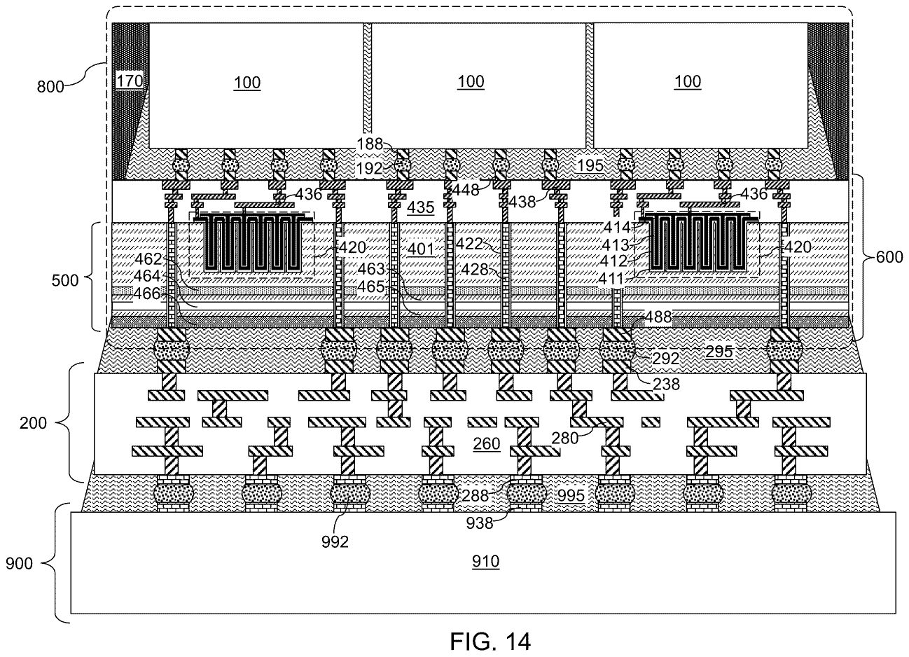

Referring to FIG. 14, a printed circuit board (PCB) 900 including a PCB substrate 910 and PCB bonding pads 938 may be provided. The PCB 900 includes a printed circuitry (not shown) at least on one side of the PCB substrate 910. An array of solder joints 992 may be formed to bond the array of board-side bonding pads 288 to the array of PCB bonding pads 938. The solder joints 992 may be formed by disposing an array of solder balls between the array of board-side bonding pads 288 and the array of PCB bonding pads 938, and by reflowing the array of solder balls. An additional underfill material portion, which is herein referred to as a board-substrate underfill material portion 995 or a BS underfill material portion 995, may be formed around the solder joints 992 by applying and shaping an underfill material. The packaging substrate 200 is attached to the PCB 900 through the array of solder joints 992.

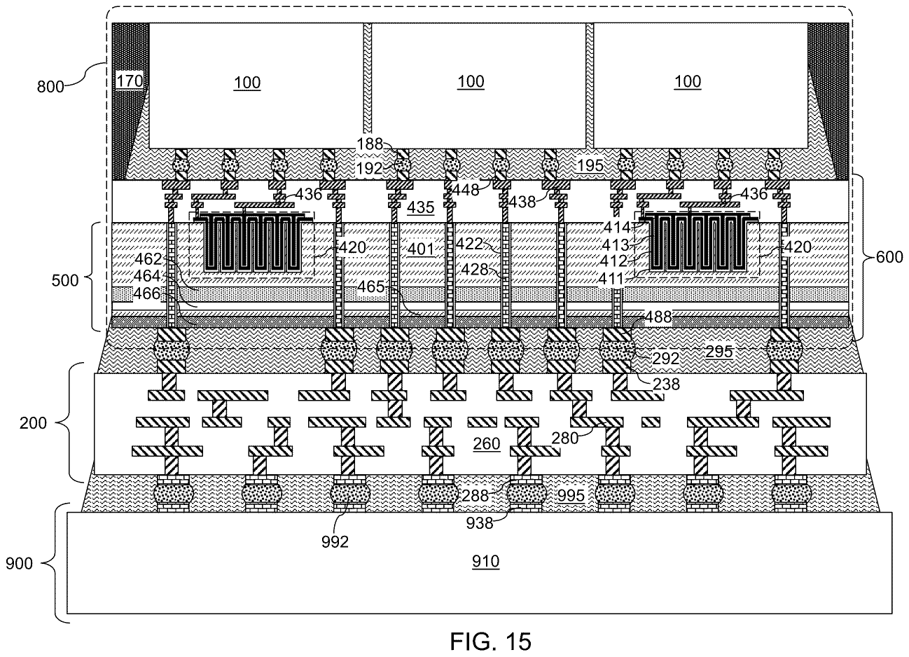

Referring to FIG. 15, a first alternative configuration of a bonded assembly of a composite package 800, a packaging substrate 200, and a printed circuit board 900 is illustrated. The first alternative configuration of the bonded assembly may be derived from the bonded assembly described with reference to FIG. 14 by removing the first backside semiconductor layer 463. In other words, the vertical distance between the first backside isolation layer 462 and the second backside isolation layer 464 may be reduced to zero by adjusting the ion implantation depths during formation of the first backside implantation layer 462′ and the second backside implantation layer 464′ so that the first backside isolation layer 462 contacts the second backside isolation layer 464.

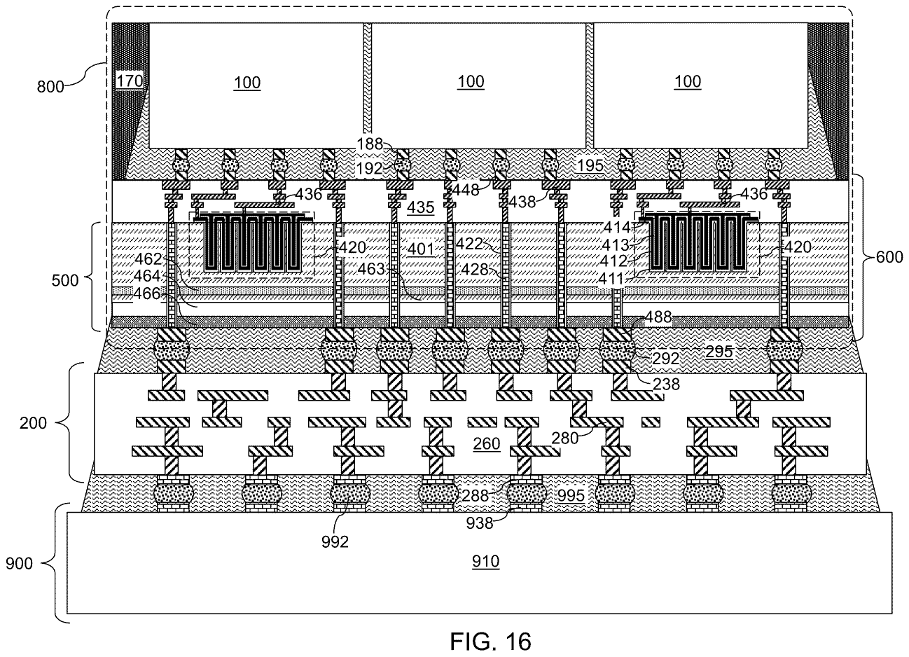

Referring to FIG. 16, a second alternative configuration of a bonded assembly of a composite package 800, a packaging substrate 200, and a printed circuit board 900 is illustrated. The second alternative configuration of the bonded assembly may be derived from the bonded assembly described with reference to FIG. 14 by removing the second backside semiconductor layer 465. In other words, the second backside isolation layer 464 may extend to the physically exposed backside surface of the reconstituted wafer 300 by reducing the ion implantation depth for formation of the second backside implantation layer 464′ so that the second backside isolation layer 464 extends to the bottom surface of the reconstituted wafer after the processing steps described with reference to FIGS. 9A and 9B.

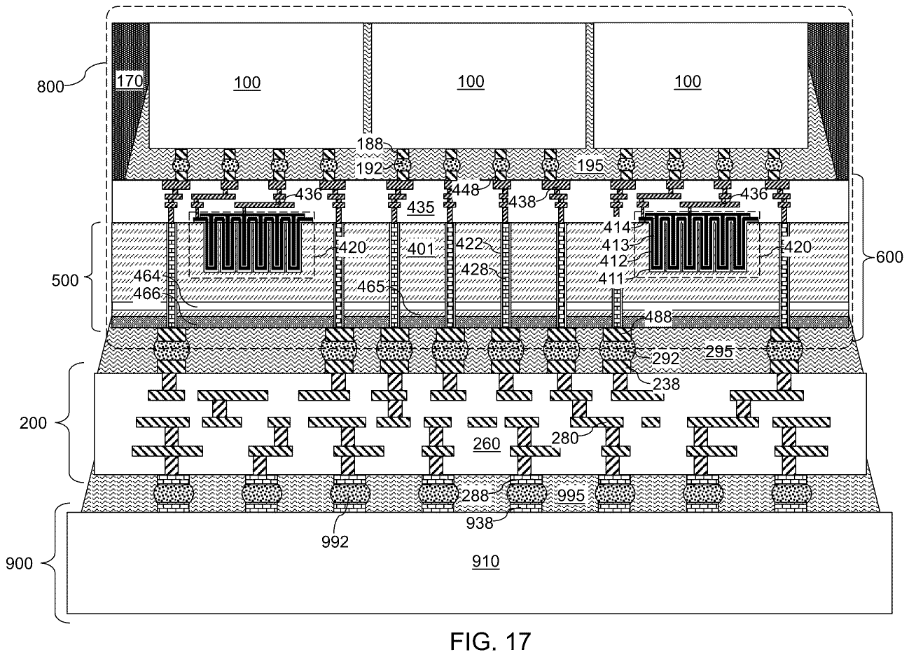

Referring to FIG. 17, a third alternative configuration of a bonded assembly of a composite package 800, a packaging substrate 200, and a printed circuit board 900 is illustrated. The third alternative configuration of the bonded assembly may be derived from the bonded assembly described with reference to FIG. 14 by omitting formation of the first backside implantation layer 462′, and thus, preventing formation of the first backside isolation layer 462. The first backside semiconductor layer 463 is also omitted, and the second backside isolation layer 464 (which is referred to as a backside isolation layer 464 in this configuration) is in direct contact with the substrate semiconductor layer 401.

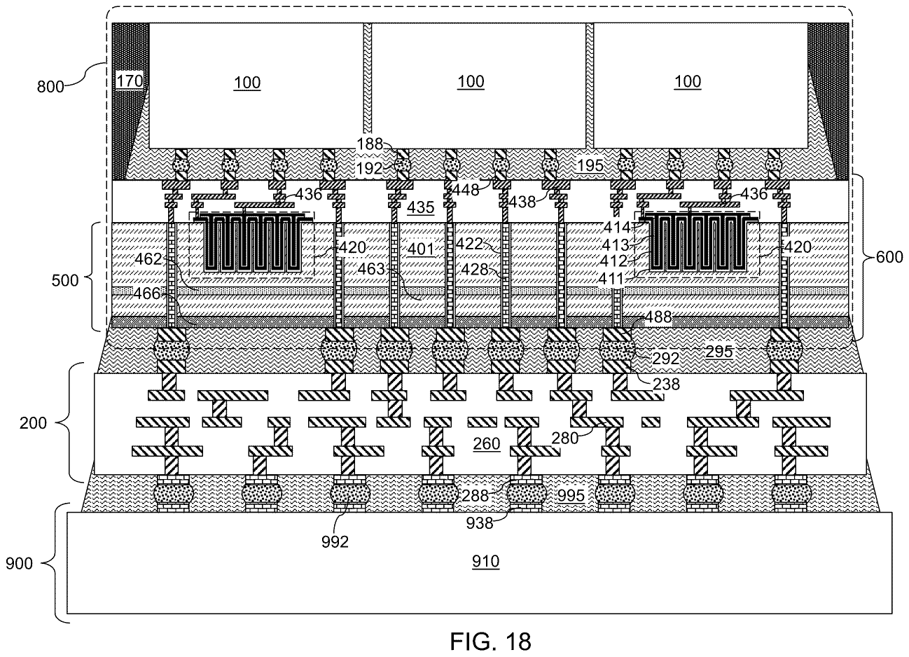

Referring to FIG. 18, a fourth alternative configuration of a bonded assembly of a composite package 800, a packaging substrate 200, and a printed circuit board 900 is illustrated. The fourth alternative configuration of the bonded assembly may be derived from the bonded assembly described with reference to FIG. 14 by omitting formation of the second backside implantation layer 464′, and thus, preventing formation of the second backside isolation layer 464. The second backside semiconductor layer 465 is also omitted, and the first backside semiconductor layer 463 (which is referred to as a backside semiconductor layer 463 in this configuration) is in direct contact with the backside passivation layer 466.

Referring collectively to FIGS. 1-18 and according to various embodiments of the present disclosure, a device structure comprising an interposer 600 is provided. The interposer 600 comprises: a substrate 500 comprising a substrate semiconductor layer 401 comprising a first portion of a semiconductor material; a semiconductor device (such as a deep trench capacitor 420) located in the substrate semiconductor layer 401; through-substrate via structures 428 vertically extending through the substrate 500; a first backside isolation layer 462 located on a backside of the substrate semiconductor layer 401 and comprising a first dielectric material including a compound of a first non-electrical dopant element and the semiconductor material; and backside bump structures 488 located on the backside end surfaces of the through-substrate via structures 428.

In one embodiment, the first backside isolation layer 462 has a first inhomogeneous vertical compositional profile ivcf_1 so that an atomic concentration of the first non-electrical dopant element is at a maximum in a middle portion of the first backside isolation layer 462 and decreases along a vertical direction from the middle portion toward an interface with the substrate semiconductor layer 401. In one embodiment, the substrate 500 further comprises a second backside isolation layer 464 located underneath the first backside isolation layer 462 and comprising a second dielectric material including a compound of a second non-electrical dopant element and the semiconductor material.

In one embodiment, the substrate 500 further comprises a backside semiconductor layer 463 interposed between the first backside isolation layer 462 and the second backside isolation layer 464 and comprising a second portion of the semiconductor material. In one embodiment, the interposer 600 comprises redistribution wiring interconnects (436, 438) embedded within redistribution dielectric layers 435 and overlying the semiconductor device (such as a deep trench capacitor 420), and further comprises interposer bump structures 448 on the redistribution wiring interconnects (436, 438); and the device structure comprises semiconductor dies 100 attached to the interposer bump structures 448.

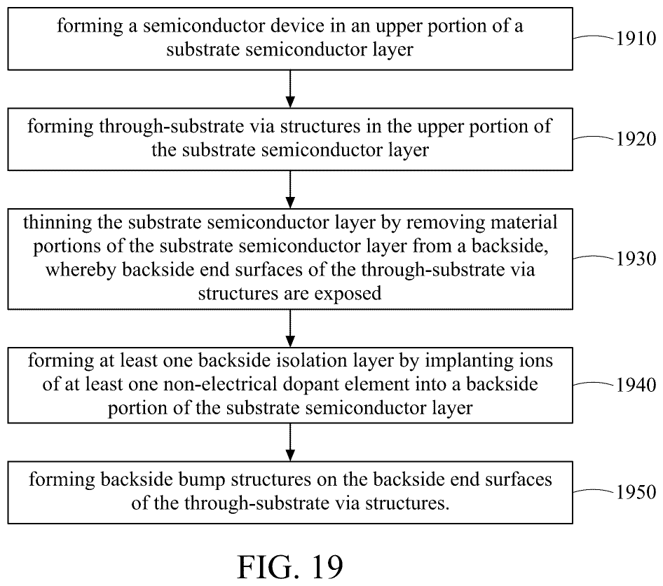

FIG. 19 is a first flowchart illustrating steps for forming a semiconductor structure according to an embodiment of the present disclosure.

Referring to step 1910 and FIGS. 1A and 1B, a semiconductor device (such as a deep trench capacitor 420) may be formed in an upper portion of a substrate 400W.

Referring to step 1920 and FIG. 2, through-substrate via structures 428 may be formed in the upper portion of the substrate 400W.

Referring to step 1930 and FIGS. 3-6 , the substrate 400W may be thinned by removing material portions of the substrate 400W from a backside, whereby backside end surfaces of the through-substrate via structures 428 are exposed.

Referring to step 1940 and FIGS. 7-9B , at least one backside isolation layer (462, 464) may be formed by implanting ions of at least one non-electrical dopant element into a backside portion of the substrate 400W.

Referring to step 1950 and FIGS. 10-18 , backside bump structures 488 may be formed on the backside end surfaces of the through-substrate via structures 428.

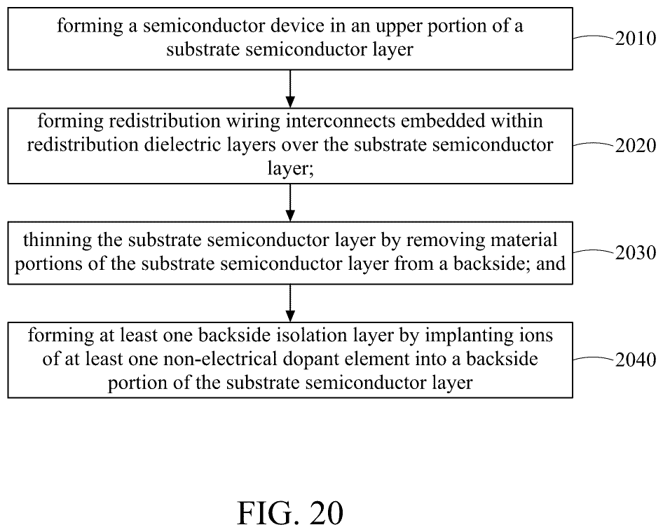

FIG. 20 is a second flowchart illustrating steps for forming a semiconductor structure according to an embodiment of the present disclosure.

Referring to step 2010 and FIGS. 1A and 1B, a semiconductor device (such as a deep trench capacitor 420) may be formed in an upper portion of a substrate 400W.

Referring to step 2020 and FIGS. 2 and 3, redistribution wiring interconnects (436, 438) embedded within redistribution dielectric layers 435 may be formed over the substrate 400W.

Referring to step 2030 and FIGS. 4-6 , the substrate 400W may be thinned by removing material portions of the substrate 400W from a backside.

Referring to step 2040 and FIGS. 7-18 , at least one backside isolation layer (462, 464) may be formed by implanting ions of at least one non-electrical dopant element into a backside portion of the substrate 400W.

Embodiments of the present disclosure provide an interposer 600 with enhanced electrical isolation by forming one or more backside isolation layers (462, 464) within the substrate 500 of the interposer 600. The one or more backside isolation layers (462, 464) are formed through ion implantation of non-electrical dopants, such as nitrogen and oxygen, into a substrate semiconductor layer 401. The interposer 600 of the present disclosure provides reduced leakage current around semiconductor devices such as deep trench capacitors 420, and around through-substrate via structures 428. The one or more backside isolation layers (462, 464) improve the overall electrical performance of the interposer 600 by increasing the electrical isolation between the semiconductor devices and the through-substrate via structures 428. Reliability of the redistribution structure (435, 436, 428) within the interposer 600 is unaffected by formation of the one or more backside isolation layers (462, 464) by utilizing a laser annealing process to promote interatomic bonding between the non-electrical dopants and the substrate material, resulting in stable and effective dielectric isolation layers that contribute to superior device reliability and reduced power consumption.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph or in different paragraphs, a Markush group including a listing of the two or more elements may also be impliedly disclosed. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method of forming a semiconductor structure, comprising:
forming a semiconductor device in an upper portion of a substrate semiconductor layer;
forming through-substrate via structures in the upper portion of the substrate semiconductor layer;
thinning the substrate semiconductor layer by removing material portions of the substrate semiconductor layer from a backside, whereby backside end surfaces of the through-substrate via structures are exposed;
forming at least one backside isolation layer by implanting ions of at least one non-electrical dopant element into a backside portion of the substrate semiconductor layer; and
forming backside bump structures on the backside end surfaces of the through-substrate via structures.

2. The method of claim 1, wherein the at least one non-electrical dopant element comprises at least one element selected from oxygen and nitrogen.

3. The method of claim 2, wherein the at least one backside isolation layer comprises a dielectric compound of the at least one non-electrical dopant element and a semiconductor material of the substrate semiconductor layer.

4. The method of claim 3, further comprising performing an anneal process after implanting ions of the non-electrical dopant element into the backside portion of the substrate semiconductor layer, wherein the anneal process increases a total number of interatomic bonds between atoms of the at least one non-electrical dopant element and atoms of the semiconductor material.

5. The method of claim 4, wherein the anneal process comprises a laser anneal process that irradiates a laser beam on the backside portion of the substrate semiconductor layer.

6. The method of claim 1, wherein:
the at least one backside isolation layer comprises a first backside isolation layer and a second backside isolation layer; and
the at least one non-electrical dopant element comprises oxygen and nitrogen.

7. The method of claim 6, wherein the first backside isolation layer and the second backside isolation layer are formed at different depths from a planar backside surface of the substrate semiconductor layer.

8. The method of claim 7, wherein the first backside isolation layer and the second backside isolation layer are vertically spaced from each other by a backside semiconductor layer that comprises an unimplanted material portion of the substrate semiconductor layer.

9. The method of claim 1, wherein the ions of at least one non-electrical dopant element are implanted between a planar backside surface of the substrate semiconductor layer and the semiconductor device.

10. A method of forming a semiconductor structure, comprising:
forming a semiconductor device in an upper portion of a substrate semiconductor layer;
forming redistribution wiring interconnects embedded within redistribution dielectric layers over the substrate semiconductor layer;
thinning the substrate semiconductor layer by removing material portions of the substrate semiconductor layer from a backside; and
forming at least one backside isolation layer by implanting ions of at least one non-electrical dopant element into a backside portion of the substrate semiconductor layer.

11. The method of claim 10, wherein the at least one non-electrical dopant element comprises one of oxygen and nitrogen.

12. The method of claim 10, wherein the at least one backside isolation layer comprises a first backside isolation layer and a second backside isolation layer that are vertically spaced from each other by a backside semiconductor layer that comprises an unimplanted portion of the substrate semiconductor layer.

13. The method of claim 10, further comprising forming through-substrate via structures in the upper portion of the substrate semiconductor layer, wherein backside end surfaces of the through-substrate via structures are exposed upon thinning the substrate semiconductor layer.

14. The method of claim 13, further comprising forming backside bump structures on the backside end surfaces of the through-substrate via structures.

15. The method of claim 10, further comprising:
forming interposer bump structures on the redistribution wiring interconnects; and
attaching semiconductor dies to the interposer bump structures, wherein the substrate semiconductor layer is thinned after attaching the semiconductor dies to the interposer bump structures.

16. A device structure comprising an interposer, wherein the interposer comprises:
a substrate comprising a substrate semiconductor layer comprising a first portion of a semiconductor material;
a semiconductor device located in the substrate semiconductor layer;
through-substrate via structures vertically extending through the substrate;
a first backside isolation layer located on a backside of the substrate semiconductor layer and comprising a first dielectric material including a compound of a first non-electrical dopant element and the semiconductor material; and
backside bump structures located on backside end surfaces of the through-substrate via structures.

17. The device structure of claim 16, wherein the first backside isolation layer has a first inhomogeneous vertical compositional profile so that an atomic concentration of the first non-electrical dopant element is at a maximum in a middle portion of the first backside isolation layer and decreases along a vertical direction from the middle portion toward an interface with the substrate semiconductor layer.

18. The device structure of claim 17, wherein the substrate further comprises a second backside isolation layer located between the first backside isolation layer and a backside surface of the substrate and comprising a second dielectric material including a compound of a second non-electrical dopant element and the semiconductor material.

19. The device structure of claim 18, wherein the substrate further comprises a backside semiconductor layer interposed between the first backside isolation layer and the second backside isolation layer and comprising a second portion of the semiconductor material.

20. The device structure of claim 16, wherein:
the interposer comprises redistribution wiring interconnects embedded within redistribution dielectric layers and overlying the semiconductor device, and further comprises interposer bump structures on the redistribution wiring interconnects; and
the device structure comprises semiconductor dies attached to the interposer bump structures.
